(19) United States
(12) Patent Application Publication
(10) Pub. No.: US 2024/0151759 A1
(43) Pub. Date: May 9, 2024

(54) MULTI-CHANNEL AUTOMATED EARTH GROUND RESISTANCE SYSTEM AND METHOD FOR MEASURING EARTH GROUND RESISTANCE

(71) Applicant: DEHN SE, Neumarkt i.d.OPf. (DE)

(72) Inventors: Sunil Saini, Gurugram (IN); Vikas Almadi, Gurugram (IN); Puneet Saini, Gurugram (IN); Anil Kumar, Gurugram (IN)

(21) Appl. No.: 18/280,586

(22) PCT Filed: Mar. 15, 2022
(86) PCT No.: PCT/EP2022/056680

§ 371 Date: Sep. 6, 2023

(30) Foreign Application Priority Data
Mar. 19, 2021 (IN) 202111011776

(51) Int. Cl. G01R 27/20

(52) U.S. Cl. CPC G01R 27/20

(57) ABSTRACT

The invention relates to a method of measuring earth ground resistance. The method comprises the steps of:
Performing an earth ground resistance measurement by means of an earth ground measurement device, thereby obtaining measurement data,
Gathering the measurement data via at least two different channels of the earth ground measurement device such that multiple measurements are performed at once, wherein each channel is configured to perform an earth ground resistance measurement, and
Uploading the measurement data automatically to a remote processing module separately formed with respect to the earth ground measurement device.

Further, a system for measuring earth ground resistance is described.

The invention relates to a method of measuring earth ground resistance. Further, the invention relates to a system for measuring earth ground resistance, particularly a multi-channel automated earth ground resistance system with cloud connectivity.

In the state of the art, earth resistance testing systems are known that are used to conduct earth ground resistance measurements or rather soil resistivity measurements, thereby providing an early warning system. Generally, a lack of good grounding is undesirable as it increases the risk of equipment failure. In fact, the lack of an effective grounding system can lead to a variety of problems. If fault currents do not have a path to the ground via a properly designed and maintained grounding system, these currents will find unintended paths, thereby causing problems to the equipment. Hence, a good grounding system is essential to prevent damage. However, corrosive soils with high moisture content, high salinity, and high temperatures can affect grounding rods and their connections, thereby varying the ground resistance over time. Therefore, it is necessary to perform grounding tests in order to become aware of any issues.

For this purpose, earth pits are installed usually that are checked periodically and manually in a subsequent manner in order to gather the resistance values at the respective sites of the earth pits. However, this requires a lot of manpower and awareness of the operators in order to keep the resistance values in check. Even though the earth pits are checked regularly, the time span between two subsequent checks may be large, for instance about six months up to a year. Thus, any incident that may occur within the time span indicated above will be noticed during the next check. Further, it is up to the human that performs the respective check to identify the incident correctly that has happened based on the resistance values measured.

It is known in the state of the art, to use an automated earth fault testing system that supports the humans when performing the checks. The automated earth fault testing systems typically comprise a remote unit that communicates with a main device via a communication link, e.g. a cable. The remote unit may be held by a single operator while standing directly adjacent to an electrode of the automated earth fault testing system, wherein the respective electrode may be placed at a large distance from the main device and/or other electrodes of the automated earth fault testing system. Accordingly, the respective checks performed in intervals are simplified due to the automated earth fault testing system having the remote unit that can be used by the single operator. For instance, US 2013/0154651 A1 does show such an earth ground tester having a remote unit.

However, the system is known so far still require that the operator manually checks several areas to be investigated in a subsequent manner in order to identify an earth fault at these sites.

Accordingly, there is need for a higher degree of automation.

The invention provides a method of measuring earth ground resistance. The method comprises the steps of:
Performing an earth ground resistance measurement by means of an earth ground measurement device, thereby obtaining measurement data,
Gathering the measurement data via at least two different channels of the earth ground measurement device such that multiple measurements are performed at once, wherein each channel is configured to perform the earth ground resistance measurement, and
Uploading the measurement data automatically to a remote processing module separately formed with respect to the earth ground measurement device.

Further, the invention provides a system for measuring earth ground resistance. The system comprises an earth ground measurement device that has a test module configured to perform earth ground resistance measurements. The earth ground measurement device comprises at least two different channels, wherein each channel is configured to perform the earth ground resistance measurement. The earth ground measurement device further has at least one communication module configured to communicate measurement data obtained to a remote processing module.

Accordingly, the method and the system both ensure that several locations can be tested at the same time by means of the same earth ground measurement device while using the at least two different channels of the earth ground measurement device. In fact, both channels are configured to perform a respective earth ground resistance measurement, e.g. by means of a three-pole method or even higher, thereby providing a deeper insight in the environment, namely the earth ground. Hence, improved earth ground resistance measurements are possible. In other words, a multi-earth pit analysis can be performed at the same time by means of the earth ground resistance measurements performed, for instance the three-pole method performed, at the multiple earth pits while using the earth ground measurement device, as the respective measurement data is collected via at least two different channels that are associated with two different sites.

Moreover, the measurement data collected is automatically uploaded to the remote processing module for being further processed automatically. Moreover, the measurement data collected may be accessed by different devices that may have access to the remote processing module irrespective of their locations. Thus, the collected data can be provided immediately elsewhere such that an operator is enabled to check the respective measurement data even though the operator is not at the respective site of the earth pits to be checked. The resistance values obtained by means of the earth ground resistance measurements are obtained and provided immediately, thereby ensuring that future incidents can be identified as soon as possible.

Moreover, the method as well as the system are generally configured to perform a three-pole method or rather a fall-of-potential method, which allows to measure energy dissipation ability of grounding system as well as any electrode.

Each channel may have at least three interfaces associated with electrodes used for performing the earth ground resistance measurement, e.g. the three-pole method. Generally, the three interfaces per channel are connected with electrodes that are placed into the earth ground for measuring purposes. Two of these electrodes are used for providing a current feedback, whereas the third of these electrodes is provided for providing a voltage feedback. The third electrode is located within the direct line of the two electrodes used for current feedback. Generally, the current feedback is provided by injecting a current and receiving a feedback of an actual current flow between these two electrode. Accordingly, one electrode is the reference which is being measured for earth ground resistance, whereas the current is injected via the other one. In other words, the two electrodes used for obtaining the current feedback correspond to the outer ones, as the third electrode is interposed between them. Accordingly, three electrodes or rather three poles are used. The three-pole measurement is also called three-point measurement or rather test, as the electrodes are located at three different points within a certain testing area.

Accordingly, the at least two different channels are used to perform the respective measurements at two different/distinct testing areas.

In addition, each channel may also be configured to perform a four-pole method or rather four-point test, as each channel has four interfaces associated with electrodes. Hence, the outer electrodes are used for the current feedback, whereas the other two electrodes are located between them, particularly on the direct line between both electrodes used for the current feedback.

As mentioned above, the electrodes are generally placed into the soil, wherein the two outer electrodes create a current loop, thereby providing the current injection path. The at least one additional electrode (three-pole measurement) or rather the other two additional electrodes (four-pole measurement) are located between the ones used for current injection and measurement. The latter one(s) may be used to measure the voltage drop across the soil within the respective testing area.

However, the electrodes may also be located in a different arrangement rather than the straight line, e.g. a star-like or triangular arrangement or even at different angles with respect to each other.

In general, the earth ground measurement device may have three different channels that each comprise at least three interfaces, thereby enabling the three-pole measurement per channel.

The three different channels may be associated with a respective phase of a three-phase power input of the earth ground measurement device.

In addition, earth leakage measurements, earth integrity measurements and/or neutral to earth voltage measurements may be performed. For instance, the system may additionally comprises an earth integrity measurement module and/or a neutral to earth voltage measurement module.

As mentioned above, the measurement data collected is automatically uploaded to the remote processing module for being further processed automatically. Hence, the measurement data collected may be accessed by different devices that may have access to the remote processing module irrespective of their locations. Thus, the collected data can be provided immediately elsewhere such that an operator is enabled to check the respective measurement data even though the operator is not at the respective site of the earth pits to be checked. Accordingly, the values of other critical parameters than the resistance values obtained by means of the ground resistance measurements may also be obtained and provided immediately, e.g. the values for neutral to earth voltage (NE volt), earth integrity and/or earth leakage current. Particularly, those values may be provided simultaneously with the measurement values obtained when performing the ground resistance measurements.

An aspect provides that a signal generator of the earth ground measurement device is controlled to generate a constant current signal that is forwarded to one electrode per channel such that a predetermined current is flowing between two respective electrodes of each channel, thereby providing a current path for feedback, wherein a third electrode per channel provides a voltage feedback. In other words, the earth ground measurement device has a control circuit that is configured to control a signal generator of the earth ground measurement device to generate a constant current signal that is forwarded to one electrode per channel such that a predetermined current is flowing between two respective electrode of each channel, thereby measuring the current feedback. A third electrode per channel is configured to provide a voltage feedback. Two of the three electrode are used for establishing a current line, thereby enabling the earth ground resistance measurement, as a current is injected that runs from the first electrode to the second electrode. In addition, the third electrode may be located between both electrodes mentioned before, e.g. along a direct line between both electrodes used for the current feedback. In fact, one of both electrodes used for the current link and feedback may also be called earth electrode, whereas the other one is connected with the signal generator that provides the respective constant current signal.

The three-pole measurement enables to automatically calculate the resistance values of the earth, e.g. the earth electrode, by using the Ohm's Law, as the constant current signal generated is known and the measured drop in potential. An analog frontend engine forwards the signal associated with the voltage feedback to a computing circuit which calculates the respective resistance values obtained by the different channels, e.g. the measurement data, is then forwarded to the separately formed remote processing module.

Another aspect provides that the remote processing module comprises a measurement data analysis circuit that processes the measurement data uploaded, thereby analyzing the measurement data automatically. Therefore, it is not necessary that the single operator has to take the respective measurements data into account manually in order to retrieve any information with regard to the measurement data or rather the resistance values obtained. The analysis is done in a completely automatic manner by means of the remote processing module, e.g. the measurement data analysis circuit.

Further, the remote processing module may be a data collection server to which the measurement data collected is automatically uploaded by means of the at least one communication module of the earth ground measurement device. The data collection server ensures that the measurement data can be collected in a centralized manner such that the measurement data can be accessed remotely.

Hence, it is not required that the operator has to be present at the respective site or rather any of the testing areas at which the earth ground resistance measurements are performed. In fact, the earth ground measurement device may communicate with the data collection server by means of a TCP/IP communication protocol, for instance via the internet.

According to a further aspect, the earth ground measurement device has a mounting interface that is configured to mount the earth ground measurement device on a DIN rail. Therefore, the earth ground measurement device may be directly connected to the DIN rail. In addition, the earth ground measurement device may have a three-phase input interface via which three-phase electric power is received. The three-phase electric power may be used internally by means of the earth ground measurement device for supplying the three different channels that are used for performing the multiple measurements at the different testing areas simultaneously and to power up the associated peripherals.

The at least one communication module may be configured to communicate via the internet protocol and/or a Modbus data communication protocol. The Modbus protocol uses character serial communication lines, Ethernet, or the Internet protocol suite as a transport layer. In fact, the at least one communication module may use the Modbus TCP frame format or rather the Modbus RTU frame format for communication purposes. The Modbus RTU uses synchronous serial data lines like RS-485 for transferring the respective measurement data. Hence, the earth ground measurement device may be a Modbus TCP embedded device while using the Modbus TCP for communication purposes, which is also called Modbus TCP/IP.

The earth ground measurement device may have an Ethernet interface via which the earth ground measurement device is enabled to communicate based on the Modbus data communication protocol.

Moreover, the at least one communication module, particularly another one with respect to the one using the Modbus data communication protocol, uses wireless network protocols based on the IEEE 802.11 family of standards, also called Wi-Fi, may be used.

Furthermore, a mobile application may run on a separate (mobile and/or smart) device, which communicates with the earth ground measurement device.

In addition, the earth ground measurement device has a graphic display, for instance a liquid crystal display (LCD), that is configured to receive data from the test module to be displayed graphically in order to inform an operator directly provided that the respective operator is present.

The earth ground measurement device further comprises an indicator like a visual indicator, for instance a light emitting diode (LED). The indicator is used to indicate a respective status of the different channels, particularly in a visual or rather graphical manner. The indicator may be used to indicate whether a respective channel measurement is healthy, open and/or unhealthy. The device allows to set a threshold value for the earth pits or the system to distinguish whether the measured resistance values are below the set threshold value, e.g. healthy, or above the threshold value, e.g. unhealthy, according to the need of the operator or user and accordingly raise an visual alarm. For instance, a multi-color LED is used to indicate the respective status of the channel.

Furthermore, the respective indicator may indicate a respective resistance value measured by means of the respective channel, thereby outputting an alert in case that the measurement provides a resistance value out of a certain range defined previously, e.g. below or above a certain threshold value. Again, the indicator may relate to a multi-color LED having the colors green, yellow and red in order to visualize three different ranges of the respective resistance value measured.

The system may comprise a data collection server that is configured to communicate with the earth ground measurement device via the communication module of the earth ground measurement device. Particularly, the earth ground measurement device communicates with the data collection server, e.g. a cloud server, via Wi-Fi and TCP/IP.

The data collection server may relate to the remote processing module that communicates with the earth ground measurement device, particularly its communication module. Thus, an earth resistance and event database may be provided by means of the data collection server, as the database encompasses resistance values gathered as well as events associated therewith. The respective database can be accessed from different locations/sites directly such that the respective measurement data can be obtained immediately, as the measurement data is automatically uploaded once it is retrieved by means of the earth ground measurement device.

Generally, the data collection server may relate to a cloud server.

Another aspect provides that the system is configured to use an injected current in the range of 2 mA to 15 mA at a frequency range up to 820 Hz. In fact, the respective current used for performing the three-pole measurement may be varied or rather set appropriately. In other words, a varying injected current in the range of 2 mA to 15 mA at various frequency ranges up to 820 Hz can be used by the earth ground measurement device in order to gather the measurement data. The measurement data gathered, namely the earth resistance values, the values for neutral to earth voltage, the values for earth integrity and/or the values for earth leakage current, is uploaded automatically to the data collection server by using the TCP/IP/Wi-Fi communication protocol.

Generally, the earth ground measurement device is configured to perform a monitoring while carrying out the three-pole measurements or higher at the different testing areas that are associated with the at least two different channels of the earth ground measurement device. The monitoring information, namely the measurement data gathered, is uploaded automatically to the data collection server, thereby ensuring that the measurement data can be accessed directly from elsewhere. Hence, an automatic and fast data collection is ensured such that any incidents can be identified immediately. Since the earth ground measurement device has two or more different channels, a multiple earth pit analysis, namely an analysis on several testing areas, can be done at once.

The forgoing aspect and many of the attendant advantages of the claim subject matter will become readily appreciated as the same become better understood by reference to the following detailed description, when taken in conjunction with the accompanying drawings. In the drawing,

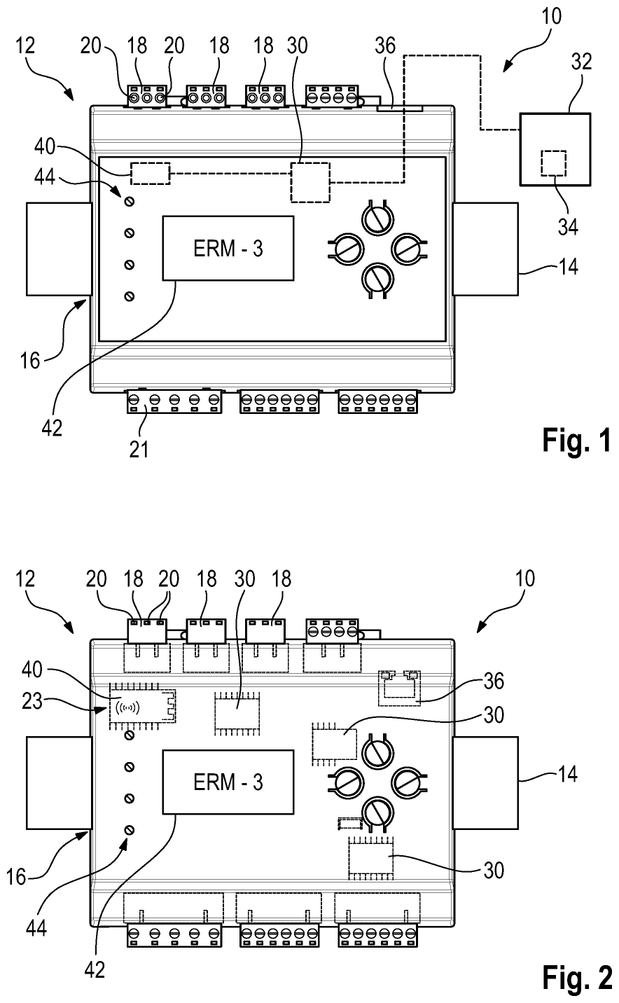

FIG. 1 schematically shows an overview of a system for measuring earth ground resistance according to the invention,

FIG. 2 shows a semi-transparent overview of the system shown in FIG. 1

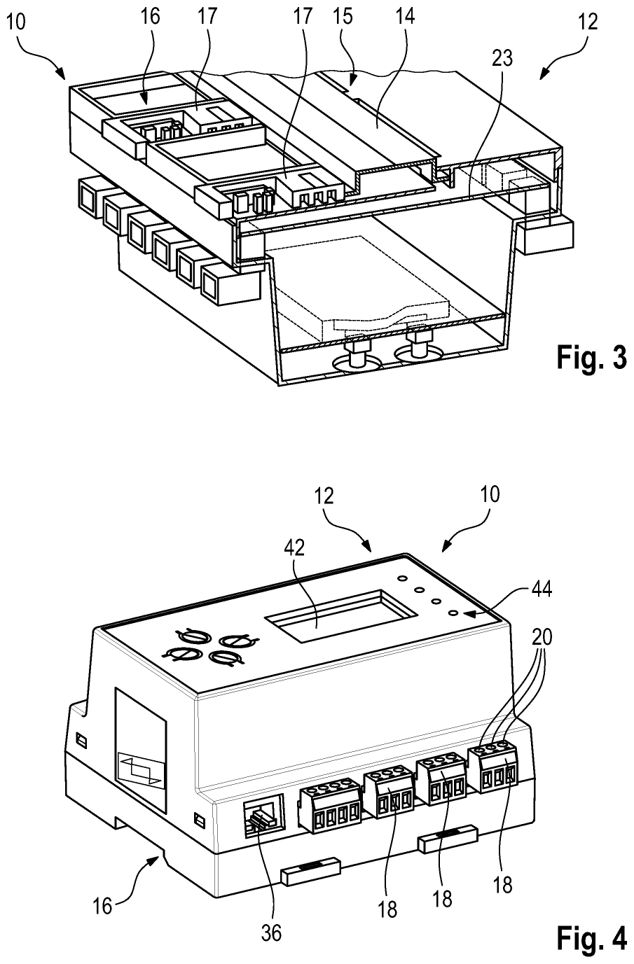

FIG. 3 shows a cross sectional view of the system shown in FIG. 1,

FIG. 4 shows an isometric view of the system shown in FIG. 1,

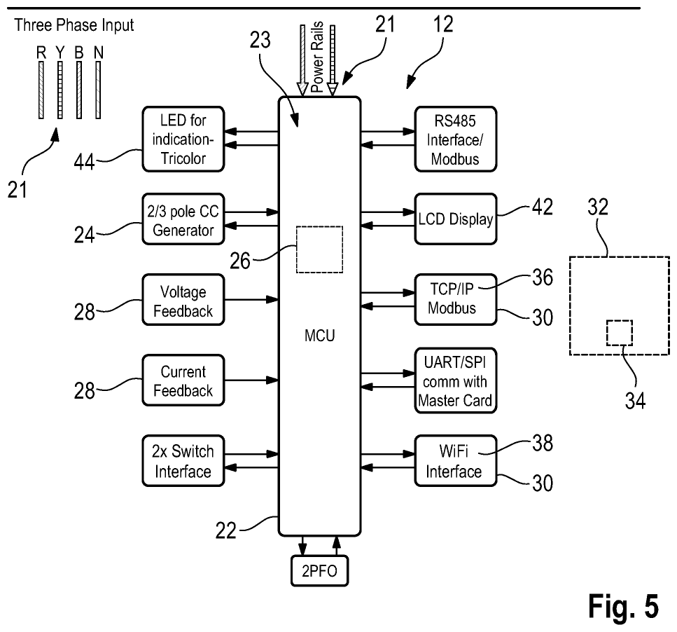

FIG. 5 shows a block diagram of the system according to FIG. 1,

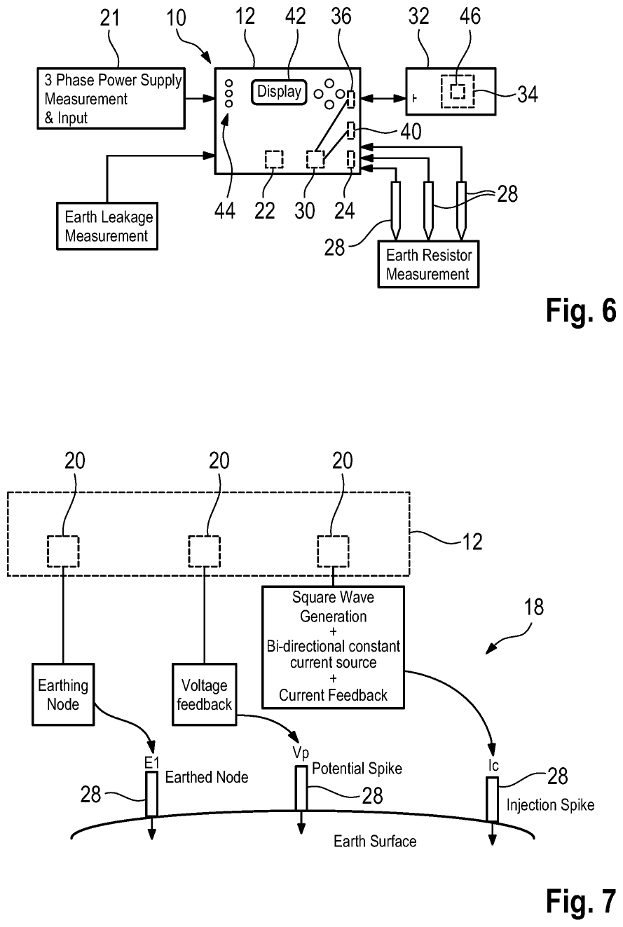

FIG. 6 shows another block diagram of the system according to FIG. 1,

FIG. 7 shows an overview of a functional diagram of one channel of the system shown in FIG. 1,

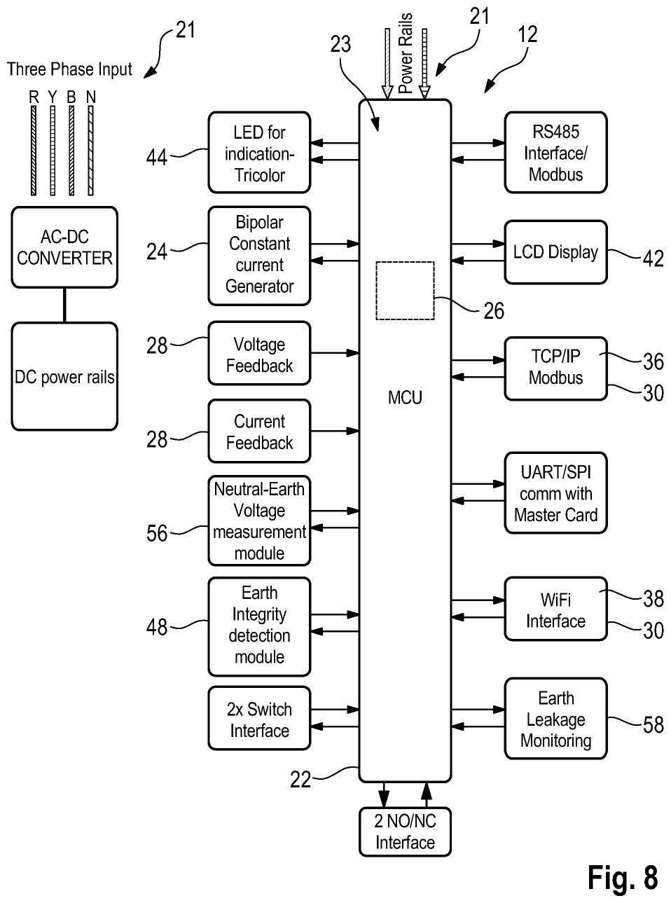

FIG. 8 shows a block diagram of the system according to the further embodiment,

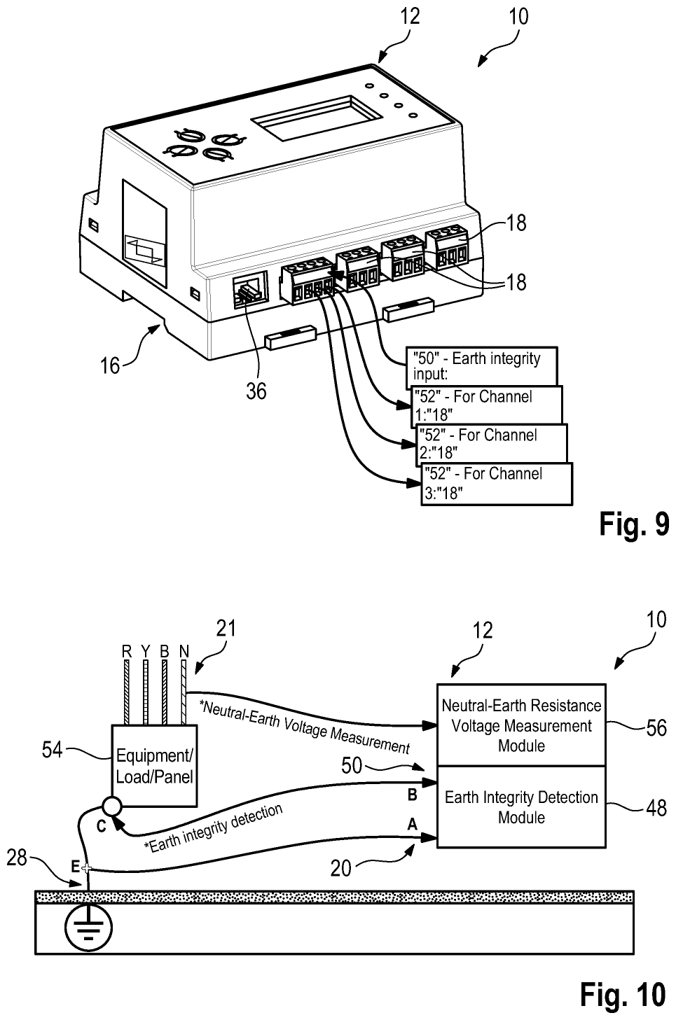

FIG. 9 shows an isometric view of the system according to a further embodiment, and

FIG. 10 shows an overview of a functional diagram of measurement performed by the further embodiment.

In FIGS. 1 to 6, a system 10 for measuring earth ground resistance is shown, wherein the system 10 comprises an earth ground measurement device 12 that is connected to a DIN rail 14.

On its rear side 15, the earth ground measurement device 12 has a mounting interface 16 via which the earth ground measurement device 12 is directly connected to the DIN rail 14. The mounting interface 16 also comprises a clamp mechanism 17 that ensures a safe mounting of the earth ground measurement device 12 on the DIN rail 14.

In the shown embodiment, the earth ground measurement device 12 has three different channels 18, wherein each of the channels 18 has three interfaces 20 that are used for performing earth ground resistance measurements. In fact, each of the channels 18 can be used for performing a three-pole method in order to perform the earth ground resistance measurements, as will be described later in more detail.

In addition, the earth ground measurement device 12 comprises a three-phase input 21, particularly by means of power rails, such that three-phase electric power is provided that is converted to appropriate required dc power rails by means of switch mode high voltage AC to DC power converter(s). Generally, low voltages in the range 1.1 V to 12 V may be achieved. The earth ground measurement device 12 can work with any two inputs available from power source used for supplying the earth ground measurement device 12.

Particularly, an internal test module 22 provided on a printed circuit board 23 is supplied by the converted electric power, wherein the test module 22 is used for performing the earth ground resistance measurements.

The respective channels 18 of earth ground measurement device 12 are connected with the internal test module 22, as the test module 22 is configured to control components of the earth ground measurement device 12 appropriately, for instance a signal generator 24.

Put differently, the test module 22, e.g. a control circuit 26 of the test module 22, is configured to control the signal generator 24 to generate a constant current signal that is forwarded to one of the interfaces 20 of the respective channel 18.

As shown in FIGS. 6 and 7, at least one interface 20 per channel 18 is connected to the signal generator 24 such that the constant current signal generated by the signal generator 24 is forwarded via the respective interface 20 to an electrode 28 connected thereto. In the shown embodiment, this electrode is called injection spike, as the constant current is injected (“l_{c}”) into the soil or rather the earth ground.

Hence, a predetermined current is generated between these two electrodes 28 of the channel 18, namely the injection spike and the earthed node that is also connected to one of the three interfaces 20 per channel 18. Both electrodes 28 may be called current electrodes, as they are used to measure a current through the earth ground for measuring the earth ground resistance. In any case, both electrodes 28 of the respective channel 18 are used to measure the current feedback of the earth ground at the respective testing location to which the electrodes 28 of the channel 18 are associated.

For instance, the system 10, particularly the earth ground measurement device 12, is configured to inject a constant current in the range of 2 mA to 15 mA at a constant frequency range up to 820 Hz.

In addition, the same channel 18 is associated with a third electrode 28 that is configured to provide a voltage feedback. The third electrode 28 is also called potential spike, as this electrode 28 provides information concerning the potential.

The third electrode 28 may be located in a direct line between both electrodes 28 used for the current feedback as indicated in FIG. 7.

Besides the earth resistance measurements or rather earth resistor measurements, the earth ground measurement device 12 is also enabled to perform an earth leakage measurement as indicated in FIG. 6. By means of the further embodiment shown in FIGS. 8 to 10, earth integrity and neutral to earth voltage measurements are performed as will be described later in more detail.

The test module 22 generally receives the measurement data of the electrodes 28, wherein the test module 22 may already be configured to analyze the measurement data obtained, thereby calculating a resistance value automatically by means of the earth ground measurement device 12.

The (pre-analyzed) measurement data, namely the raw data or the automatically calculated resistance values (or the values for neutral to earth voltage, the values for earth integrity and/or the values for earth leakage current—as shown in the further embodiment), may be forwarded from the test module 22 to a communication module 30 that is configured to communicate the respective information to a remote processing module 32, e.g. a data collection server 34.

In the embodiment shown, the communication module 30 is connected to an Ethernet interface 36 that can be used for communicating with the remote processing module 32, namely the data collection server 34, by using a Modbus data communication protocol, particularly Modbus TCP/IP.

In other words, the earth ground measurement device 12 is enabled to automatically upload the data obtained to the remote processing module 32 via the Ethernet interface 36 connected with the communication module 30, wherein the remote processing module 32 is formed separately with respect to the earth ground measurement device 12. For instance, the remote processing module 32 is located in another country compare to the site at which the earth ground measurement device 12 is installed.

The respective communication established between the earth ground measurement device 12, e.g. the communication module 30, and the data collection server 34 may be done my means of the internet protocol (IP) and/or the Modbus data communication protocol as indicated above, e.g. a Modbus TCP or Modbus RTU.

Alternatively or additionally, the earth ground measurement device 12 has a Wi-Fi communication module 38 or rather Wi-Fi communication interface 40 via which the respective measurement data can be communicated in a wireless manner.

In addition, the earth ground measurement device 12 has a display 42 on which the measurement data, particularly the resistance values, are displayed for informing an operator that is operating the earth ground measurement device 12 directly.

In addition to the display 42, an indicator 44, particularly a light emitting diode (LED), may be provided that also provides a visual feedback to the operator concerning the status of the measurements performed by each of the channels 18. Hence, each channel 18 may be associated with its own indicator 44 that may illustrate different status. Alternatively, the indicator 44 provides a visual feedback of the resistance value obtained by the respective channel 18.

In FIGS. 8 to 10, the further embodiment of the system 10 is shown that is substantially similar to the embodiment shown and discussed previously. Therefore, reference is made to the foregoing explanations wherein only differences are discussed hereinafter in more detail.

As shown in FIG. 8, the system 10, e.g. the earth ground measurement device 12, also comprises an earth integrity measurement module 48, also called earth integrity detection module. The earth integrity measurement module 48 is connected with the internal test module 22 provided on the printed circuit board 23 in a bidirectional manner such that data can be exchanged in both directions.

The earth integrity measurement module 48 comprises or rather is associated with a direct current (DC) constant current generator that provides a direct current that typically ranges from few ρA to few mA. For instance, the constant current generator 24 may be used by the earth integrity measurement module 48.

In addition, the earth integrity measurement module 48 has an analog frontend or a signal conditioning block and a measuring engine, i.e. a microcontroller or a standalone ASIC. Based on the analysis performed by measuring engine the results of earth integrity status are determined.

As shown in FIG. 9, the earth ground measurement device 12 has one input port 50 with three interfaces 52. Each interface 52 is referenced with respect to dedicated electrodes 28 connected to the respective interface 20 at each channel 18.

A constant current is injected out of interface 52 via port 50 to an external arrangement 54 that is shown in FIG. 10 in more detail to which reference is made hereinafter.

As shown in FIG. 10, the current injected takes a return path via the respective interface 20 at the corresponding channel 18.

When referring to FIG. 10, it is shown that the constant current is injected from earth integrity measurement module 48 into the external arrangement 54 connected at point C. The external arrangement 54 is already connected to at least one of the earth electrodes 28. The injected current takes a return path in a loop along points BCEA as shown in FIG. 10.

Accordingly, the respective measurement and detection engine inside the earth detection module 48 analyses and performs predetermined tasks to identify the integrity of the external arrangement 54 connected to the at least one earth electrode 28.

As further shown in FIG. 8, the system 10, e.g. the earth ground measurement device 12, also comprises a neutral to earth voltage measurement module 56 which is also connected with the internal test module 22 provided on the printed circuit board 23 in a bidirectional manner such that data can be exchanged in both directions.

The neutral to earth voltage measurement module 56 comprises a frontend or a signal conditioning block and a measuring engine, i.e. a microcontroller or a standalone ASIC. Based on the measurement performed by the measuring engine the results of neutral to earth voltage are determined.

As already discussed above, the earth ground resistance measurement device 12 comprises a three-phase input 21. The neutral interface point of the three phase input 21 is internally connected to the neutral earth voltage measurement module 56 as shown in FIG. 10.

The analog frontend and signal conditioning of the neutral earth voltage measurement module 56 computes the voltage amplitude between the neutral interface point of the three phase input 21 and one of the electrodes 28 connected to interface 20 of the respective channel 18 of the system 10, e.g. the earth ground measurement device 12.

In addition, a separately formed earth leakage monitoring module 58 is provided as shown in FIG. 8, which is configured to perform the earth leakage measurements already discussed with respect to FIG. 6 previously. The separately formed earth leakage monitoring module 58 is connected with the internal test module 22 provided on the printed circuit board 23 in a bidirectional manner such that data can be exchanged in both directions.

Generally, the earth ground measurement device 12 is configured to perform earth ground resistance measurements by each of the three different channels 18 that have three interfaces 20 accordingly. Further, the earth ground measurement device 12 is configured to perform earth leakage measurements, earth integrity measurements and/or neutral to earth voltage measurements. Hence, multiple measurements may be performed at once.

The measurement data obtained, namely the raw measurement data, the resistance values calculated, the values for the earth leakage measurements, the values for the earth integrity measurements and/or the values for the neutral to earth voltage measurements, are automatically to the remote processing module 32, namely the data collection server 34.

The remote processing module 32, particularly the data collection server 34, may have a measurement data analysis circuit 46 that analyzes the measurement data uploaded to provide a deeper insight. For instance, measurement data gathered from different sites by means of different or rather several earth ground measurement devices 12 can be compared with each other, thereby providing an enhanced analysis. In other words, the data collection server 34 relates to a cloud server that gathers/collects data around the world.

Moreover, the data collection server 34 can be accessed easily such that the measurement data can be analyzed directly.

1. A method of measuring earth ground resistance, the method comprising the steps of:
Performing an earth ground resistance measurement by means of an earth ground measurement device, thereby obtaining measurement data,
Gathering the measurement data via at least two different channels of the earth ground measurement device such that multiple measurements are performed at once, wherein each channel is configured to perform the earth ground resistance measurement, and
Uploading the measurement data automatically to a remote processing module separately formed with respect to the earth ground measurement device.

2. The method according to claim 1, wherein a signal generator of the earth ground measurement device is controlled to generate a constant current signal that is forwarded to one electrode per channel such that a predetermined current is generated between two respective electrodes of each channel, thereby providing a current feedback, and wherein a third electrode per channel provides a voltage feedback.

3. The method according to claim 1, wherein the remote processing module comprises a measurement data analysis circuit that processes the measurement data uploaded, thereby analyzing the measurement data automatically.

4. The method according to claim 1, wherein the remote processing module is a data collection server to which the measurement data collected is automatically uploaded by means of the at least one communication module of the earth ground measurement device.

5. The method according to claim 1, wherein earth leakage measurements, earth integrity measurements and/or neutral to earth voltage measurements are performed.

6. A system for measuring earth ground resistance, wherein the system comprises an earth ground measurement device, wherein the earth ground measurement device has a test module configured to perform earth ground resistance measurements, wherein the earth ground measurement device comprises at least two different channels, wherein each channel is configured to perform an earth ground resistance measurement, and wherein the earth ground measurement device further has at least one communication module configured to communicate measurement data obtained to a remote processing module.

7. The system according to claim 6, wherein the earth ground measurement device has a control circuit that is configured to control a signal generator of the earth ground measurement device to generate a constant current signal that is forwarded to one electrode per channel such that a predetermined current is generated between two respective electrodes of each channel, thereby measuring a current feedback, and wherein a third electrode per channel is configured to provide a voltage feedback.

8. The system according to claim 6, wherein the earth ground measurement device has a mounting interface that is configured to mount the earth ground measurement device on a DIN rail.

9. The system according to claim 6, wherein the at least one communication module is configured to communicate via an Internet Protocol and/or a Modbus data communication protocol, particularly Wi-Fi, Modbus TCP or Modbus RTU.

10. The system according to claim 6, wherein the system comprises a data collection server that is configured to communicate with the earth ground measurement device via the communication module of the earth ground measurement device.

11. The system according to claim 6, wherein the system is configured to use an injected current in the range of 2 mA to 15 mA at a frequency range up to 820 Hz.

12. The system according to claim 6, wherein the system also comprises an earth integrity measurement module and/or a neutral to earth voltage measurement module.
